(19) United States
(12) Patent Application Publication
(10) Pub. No.: US 2015/0020868 A1
(43) Pub. Date: Jan. 22, 2015

(54) THIN FILM SOLAR CELL AND METHOD FOR MANUFACTURING SAME

(71) Applicant: HONDA MOTOR CO., LTD., Tokyo (JP)

(72) Inventors: Satoshi Oyama, Hagagun (JP); Tomoyuki Kume, Hagagun (JP)

(21) Appl. No.: 14/378,244

(22) PCT Filed: Jan. 23, 2013
(86) PCT No.: PCT/JP2013/051290

§ 371 Date: Aug. 12, 2014

(30) Foreign Application Priority Data
Feb. 14, 2012 (JP) 2012-029869

(51) Int. Cl. H01L 31/05; H01L 31/18; H01L 31/0224

(52) U.S. Cl. CPC H01L 31/0516; H01L 31/022441; H01L 31/186
USPC 136/249; 438/80

(57) ABSTRACT

A thin-film solar cell includes a substrate, a back surface electrode layer, a light-absorbing layer, and a transparent electrode layer, layered on the substrate, in this order. The layers are divided into multiple unit cells by a scribed groove, and the cells serially connected. At an inside of an end side of the solar cell perpendicular to the scribed groove, a groove is formed perpendicular to the scribed groove and has the back surface electrode is removed therefrom. The thin-film solar cell is produced by emitting a laser beam on the solar cell element of an end part of a side perpendicular to the scribed groove so as to form a new end surface by removing the back surface electrode layer, the light-absorbing layer and the transparent electrode layer, and mechanically forming the perpendicular groove perpendicular to the scribed groove, at inside of the new end surface.

### TECHNICAL FIELD

The present invention relates to a method for producing a thin-film solar cell, such as a chalcopyrite-type thin-film solar cell, in which a light-absorbing layer contains a chalcopyrite-based compound, and in particular, relates to a technique to improve power output of the thin-film solar cell,

### BACKGROUND ART

A solar cell is generally classified as a single-crystal solar cell, a poly-crystal solar cell, a thin-film solar cell, etc. Among these, the thin-film type solar cell has been developed and is commercialized, since it has an advantage in that the amount of raw material used is less than in other types of solar cells for the same power output, and an advantage in that production processing is easier and less energy is required.

A chalcopyrite-type thin-film solar cell, which is a kind of thin-film type solar cell, has a CIGS layer including a chalcopyrite based compound (for example, Cu (In₁₋ₓGaₓ)Se₂, hereinafter referred to as “CIGS”) as a p-type light-absorbing layer, comprises a substrate, a back surface electrode layer, a p-type light-absorbing layer, an n-type buffer layer and a transparent electrode layer as a basic structure, and generates electric power from the back surface electrode layer and the transparent electrode layer by irradiating light thereon.

FIG. 1 is a plan view showing a light-receiving surface of a typical chalcopyrite-type thin-film solar cell having such a CIGS layer as a light-absorbing layer, and FIG. 2 is a cross sectional view taken along line A-A in FIG. 1. In this solar cell, back surface electrode layer 11 (11a to 11d) functioning as a cathode, is formed on the substrate 10 by sputtering or the like. A light-absorbing layer 12 (12a to 12d) containing Cu—In—Ga—Se (hereinafter both the p-type light-absorbing layer and the n-type buffer layer are combined and simply referred to as the light-absorbing layer) is formed on the back surface electrode layer 11, and a transparent electrode layer 13 (13a to 13d) comprising ZnO, ZnAlO or the like is formed thereon. As shown in FIG. 2, a unit cell a (11a, 12a and 13a), a unit cell b (11b, 12b and 13b), a unit cell c (11c, 12c and 13c), and a unit cell d (11d, 12d and 13d) are connected in series by connecting a back surface electrode layer and a transparent electrode layer that are adjacent to each other.

FIGS. 3A to 3G show a process of layering the thin-film solar cell in which unit cells are multiply connected so as to yield the desired voltage. First, the back surface electrode layer 11, functioning as a cathode, is formed on the glass substrate 10 by sputtering or the like, as shown in FIGS. 3A and 3B, and the back surface electrode layer 11 is divided into multiple areas 11a and 11b by a cutting means such as physical scribing by a metallic needle or the like, as shown in FIG. 3C. Next, a light absorbing layer precursor consisting of Cu—In—Ga is formed on the back surface electrode layer 11, as shown in FIG. 3D, and subsequently, Se is dispersed in the light absorbing layer precursor so as to form the p-type light absorbing layer consisting of CIGS. Furthermore, the buffer layer is formed on the light-absorbing layer. The situation in which the light absorbing layer 12 consisting of the p-type light absorbing layer and the buffer layer is stacked, is shown in FIG. 3D. Then, the light absorbing layer 12 is divided into multiple areas 12a and 12b by a cutting means, as shown in FIG. 3E. Finally, the transparent electrode layer 13 is formed on the light absorbing layer 12, as shown in FIG. 3F, and the transparent electrode layer 13 and the light absorbing layer 12 are cut by a cutting means to divide the transparent electrode layer 13 into multiple areas 13a and 13b, as shown in Fig. and as a result, conventional thin-film solar cells in which unit cells are multiply and serially connected are obtained.

According to such a method for production, by repeating the layering process and dividing process, as shown in FIG. 3G; a unit cell is formed having the divided back surface electrode layer 11 a as a cathode, the divided transparent electrode layer 13a as an anode and the divided light absorbing layer 12a therebetween; and a unit cell is also formed having the divided back surface electrode layer 11b as a cathode, the divided transparent electrode layer 13b as an anode and the divided light absorbing layer 12b therebetween; and a structure is obtained in which a lower edge part of L-shaped transparent electrode layer 13a is connected to the back surface electrode layer 11b of an adjacent unit cell so as to serially connect these unit cells. Furthermore, similarly, a thin-film solar cell in which necessary numbers of unit cells are serially connected can be formed.

Conventionally, as a structure in which such a solar cell is sealed in a module, a structure is known in which a cover glass is stacked on a substrate having a solar cell element thereon via a sealing material and a surface of the substrate of opposite to the cover glass side is covered with a back sheet.

On the other hand, Patent Document 1 below discloses a structure in which the back sheet is omitted and seal material is arranged around a circumferential part of the substrate glass and the cover glass, that is, a structure in which glass faces glass.

However, in the glass-facing-glass structure, it is necessary to form a space to form the seal part at an end part of the glass substrate, as shown in FIGS. 4A and 4B, and an area 40 which is a circumferential part of a solar cell element should be removed so as to expose substrate 10.

However, the back surface electrode layer 11 consisting of a metal such as molybdenum or the like is strongly adhered to the glass substrate 10, and in order to remove it and expose the substrate 10, it is necessary to perform irradiation with a laser having a high power output.

However, in the case in which a laser having such a high power output is used, an end part 32 of the light absorbing layer 12 in FIG. 4B is modified by heat, increasing electrical conductivity, and as a result, current leakage may occur between the back surface electrode layer 11 and the transparent electrode layer 13 so as to decrease shunt resistance, and in the worst case, short-circuiting may occur.

As a technique to prevent such phenomenon in which an end part of the light absorbing layer is modified by heat and the solar cell element is negatively affected, as shown in FIGS. 5A and 5B, a technique can be considered in which a first area 40 is removed by a laser of high power output and a second area 41 is removed by scribing to expose the back surface electrode layer 11 before or after the laser removal of the first area 40. By this technique, the light absorbing layer 12 remaining as a solar cell element and the area 40 removed by a laser of high power output are not directly contacted to each other, and negative effect on the light absorbing layer 12 by heat can be controlled.

Patent Document 1 is Japanese Unexamined Patent Application Publication No. 2009-188357

### SUMMARY OF THE INVENTION

However, in this method, since the area 41 having a width to some extent should also be removed in addition to the area 40, it may require time for processing, and production efficiency may be decreased.

The present invention has been completed in view of the above circumstances, and objects of the present invention are to provide a method for producing a thin-film solar cell in which an area of a circumferential part of the thin-film solar cell in which the back surface electrode layer and the transparent electrode layer may short-circuit by heat of a laser beam can be removed from the solar cell element by an easier working process, and to provide a solar cell produced by the method.

The thin-film solar cell of the present invention includes a substrate, and a back surface electrode layer, a light-absorbing layer, and a transparent electrode layer, stacked on the substrate, in this order, the layers are divided into multiple unit cells by scribed grooves, and the unit cells are serially connected, wherein at an inside of an end side of the solar cell perpendicular to the scribed groove, a perpendicular groove is formed that is perpendicular to the scribed groove and that is a groove of which above the back surface electrode is removed.

The method for producing the thin-film solar cell of the present invention includes steps of: a process to form a back surface electrode layer on an upper surface of the substrate, a process to cut the back surface electrode layer to divide it into multiple back surface electrode layers, a process to form a light-absorbing layer and a transparent electrode layer on the multiple back surface electrode layers, a process to cut the light-absorbing layer and the transparent layer to form a scribed groove and to divide the solar cell element, a process to emit a laser beam onto the solar cell element of an end part of side perpendicular to the scribed groove so as to form a new end surface by removing the back surface electrode layer, the light-absorbing layer and the transparent electrode layer, a process in which a perpendicular groove which is a groove formed by removing above the back surface electrode layer is mechanically formed perpendicular to the scribed groove, at an inside of the new end surface.

Furthermore, the method for producing the thin-film solar cell of the present invention includes steps of: a process to form a back surface electrode layer on an upper surface of the substrate, a process to cut the back surface electrode layer to divide it into multiple back surface electrode layers, a process to form a light-absorbing layer and a transparent electrode layer on the multiple back surface electrode layers, a process to cut the light-absorbing layer and the transparent layer to form a scribed groove and to divide the solar cell element, a process in which a perpendicular groove, which is a groove formed by removing above the back surface electrode layer is mechanically formed perpendicular to the scribed groove, at the solar cell element of an end part of side perpendicular to the scribed groove, a process to emit a laser beam onto a part that is apart at a predetermined distance or more from the perpendicular groove of the remaining solar cell element at an end part of a side perpendicular to the scribed groove, so as to remove the back surface electrode layer, the light-absorbing layer and the transparent electrode layer.

In the present invention, it is desirable that the perpendicular groove be formed at a point having a heat relaxation distance from the new end surface modified by the laser emission, the heat relaxation distance is a distance at which the light absorbing layer is not affected by the modification.

Conventionally, the circumferential part of the thin-film solar cell in which the back surface electrode layer and the transparent electrode layer are short-circuited by influence of heat of a laser beam has been removed by removing an area having a certain width including the part affected by heat; however, in the present invention, the heat affected part can be electrically cut off from the solar cell element only by forming the perpendicular groove having a narrow linear shape, and working process is easy, and thus production efficiency of the thin-film solar cell can be improved.

### BRIEF DESCRIPTION OF DRAWINGS

FIG. 1 is a plan view showing a basic structure of a thin-film solar cell.

FIG. 2 is a cross sectional view taken along line A-A in FIG. 1, showing a basic structure of a thin-film solar cell.

FIG. 3 is a schematic cross sectional view showing a process for production of a thin-film solar cell.

FIG. 4A is a plan view, and

FIG. 4B is a cross sectional view taken along line B-B or C-C in FIG. 4A, both showing a conventional process for treatment of a circumferential part of a thin-film solar cell.

FIG. 5A is a plan view, and

FIG. 5B is a cross sectional view taken along line D-D or E-E in FIG. 5A, both showing a conventional process for treatment of a circumferential part of a thin-film solar cell.

FIG. 6A is a plan view, and

FIG. 6B is a cross sectional view taken along line F-F in FIG. 6A, both showing a process for treatment of a circumferential part of a thin-film solar cell of the invention.

FIG. 7 is a graph showing FF (Fill Factor) of an Example and Comparative Examples.

FIG. 8 is a graph showing Rₛₕ (shunt resistance) of an Example and Comparative Examples.

FIG. 9 is a graph showing Pₘₐₓ (maximal power output) of an Example and Comparative Example.

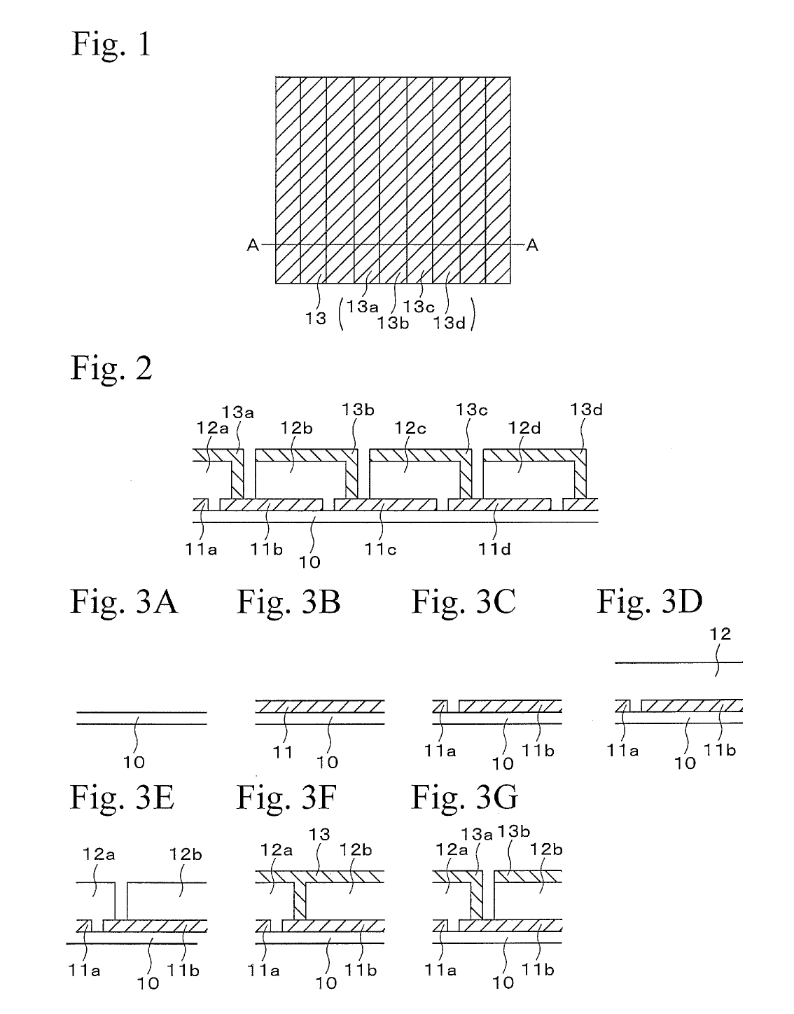

### BEST MODE FOR CARRYING OUT THE INVENTION

Hereinafter the Embodiment of the present invention is explained in detail with reference to the drawings.

The method for producing the chalcopyrite-type thin-film solar cell of the present invention is explained. That is, first, as shown in FIG. 3A and 3B, film of a back surface electrode layer 11 comprising Mo metal or the like and functioning as an anode is formed on a substrate 10 comprising soda lime glass (SLG) or the like by a sputtering method or the like using a Mo metal target or the like.

The back surface electrode layer is cut by a cutting means that has a scribing blade on the top thereof or that has a laser, and as shown in FIG. 3C, it is divided into back surface electrode layers 11a and 11b, which are multiply divided via a separate groove. Next, as shown in FIG. 3D, film of precursor of a light absorbing layer comprising Cu—In—Ga is formed on the back surface electrode layer 11, and then, by performing heat treatment in a hydrogen selenide (H₂Se) atmosphere, which is a treatment to disperse Se in the light absorbing layer precursor, a p-type light absorbing layer comprising CIGS is formed. Furthermore, a buffer layer comprising CdS, ZnS, or InS, for example, is formed on the light absorbing layer by a chemical bath deposition method. FIG. 3D shows the situation in which a light absorbing layer 12 consisting of the p-type light absorbing layer and buffer layer is layered.

Next, as shown in FIG. 3E, the light absorbing layer 12 is divided into multiple areas 12a and 12b by a cutting means. In addition, as shown in FIG. 3F, a transparent electrode layer 13 comprising ZnO, ZnAlO or the like is formed on the light absorbing layer 12.

Finally, as shown in FIG. 3G, the transparent electrode layer 13 and the light absorbing layer 12 are cut together by a cutting means so as to divide the transparent electrode layer 13 into multiple areas 13a and 13b, thereby obtaining the thin-film solar cell in which multiple unit cells are connected in series.

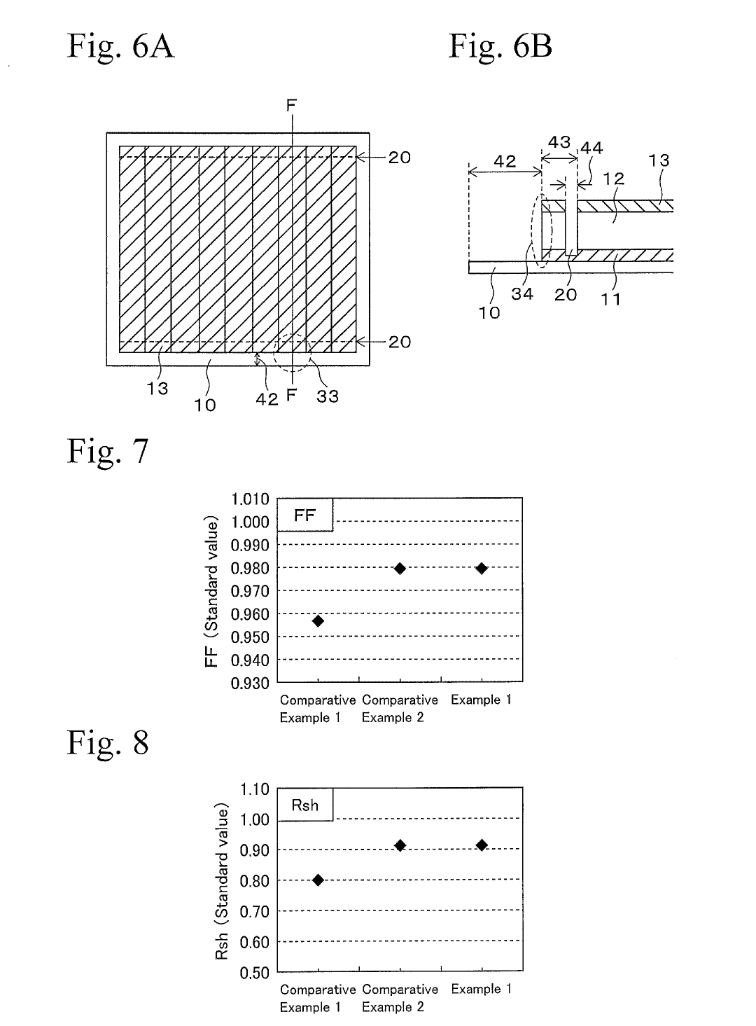

Subsequently, a process of removing a circumferential part of a solar cell element is started in order to obtain a glass-facing-glass structure of the thin-film solar cell obtained and a cover glass (not shown in the figure), and in order to make a space to fill sealing material around the solar cell element. In this process, as shown in FIG. 6, in an area 42, the back surface electrode layer 11, light absorbing layer 12 and transparent electrode layer 13 are removed from the substrate 10.

Since the back surface electrode layer 11 is strongly fixed on the substrate 10, in this removing process, it is difficult to remove such a wide area like the area 42 by a mechanical cutting means such as scribing.

Therefore, in order to remove the area 42, a high output laser such as one having a power output of 15 W, should be emitted, for example. Due to such high power output laser emitting, the light absorbing layer 12 may be modified such that the Cu/In ratio of the light absorbing layer is increased, electric conductivity is increased, and shunt resistance may be decreased or short circuited near an end part 34.

The invention is characterized in that a perpendicular groove 20, which is perpendicular to the multiple scribed grooves dividing the unit cells, is formed at a heat relaxation distance 43 from the end part 34. According to the perpendicular groove 20, the end part 34, which exists between the back surface electrode layer 11 and the transparent electrode layer 13 and which is modified to have electrical conductivity, is electrically separated from the right side of the perpendicular groove 20, that is, from the solar cell element. As a result, the problem of decrease of shunt resistance and short circuiting, which would badly affect the entirety of the solar cell element, can be solved.

Since the perpendicular groove 20 can be formed by simply scribing mechanically using a cutting means, such as needle, to form a linear groove, it is not necessary to remove the entirety of the part corresponding to the heat relaxation distance 43 as in the conventional situation, and processing efficiency is improved. Furthermore, as shown in FIG. 6B, in the perpendicular groove 20, it is not always necessary to remove the back surface electrode layer 11 completely, and a left part and a right part of the perpendicular groove 20 can be insulated if most of the light absorbing layer 12 is removed. Therefore, other than the mechanical cutting means, a low power output laser or a chemical method such as chemical etching can be used.

The heat relaxation distance 43 of the present invention is desirably about 10 μm to 1 mm, and more desirably is several hundreds of μm. This heat relaxation distance 43 is appropriately set depending on output of the high power output laser during removing of the area 42.

Width 44 of the perpendicular groove 20 in the present invention is not limited in particular as long as the perpendicular groove 20 insulates both side areas thereof, and it relies on selection of a cutting means such as a laser, needle, or etching which is selected in order to form the perpendicular groove. Typically, the width of the perpendicular groove is several μm to several tens of μm.

Since the perpendicular groove 20 is formed by using a mechanical method such as a needle, low power output laser, or chemical etching, there is no deleterious effect in which electric conductivity is imparted to the light absorbing layer facing this groove. Furthermore, time and cost may be increased even if the entire area in the vicinity of the end part is removed by a needle; however, in the present invention, there is no such problem since only one perpendicular groove is formed.

As explained so far, by the present invention, by separating the short circuiting part of the back surface electrode layer and the transparent electrode layer at the circumferential part of solar cell by the perpendicular groove, deleterious effects of the short circuiting part of the end part of the solar cell to the entirety of the solar cell can be prevented.

### EXAMPLES

Hereinafter, the present invention is explained in detail with reference to Examples and Comparative Examples.

### Example 1

By the method for production mentioned above, a back surface electrode layer having a thickness of 0.4 μm, a light absorbing layer having a thickness of 1.4 μm, and a transparent electrode layer having a thickness of 0.6 μm were formed on a glass substrate, in this order, so as to produce a thin-film solar cell. An area 42 to be removed, which is a circumferential part of the solar cell shown in FIG. 6 was set at 6.4 mm, and this area was removed by a laser having a power output 15 W. Perpendicular grooves are formed at both sides of the solar cell at the heat relaxation distance from the end, so as to obtain the thin-film solar cell of Example 1. It should be noted that the heat relaxation distance 43 was set 100 μm and width 44 of the perpendicular groove 20 was set 40 μm, so as to remain 60 μm to the outside of the perpendicular groove.

### Comparative Example 1

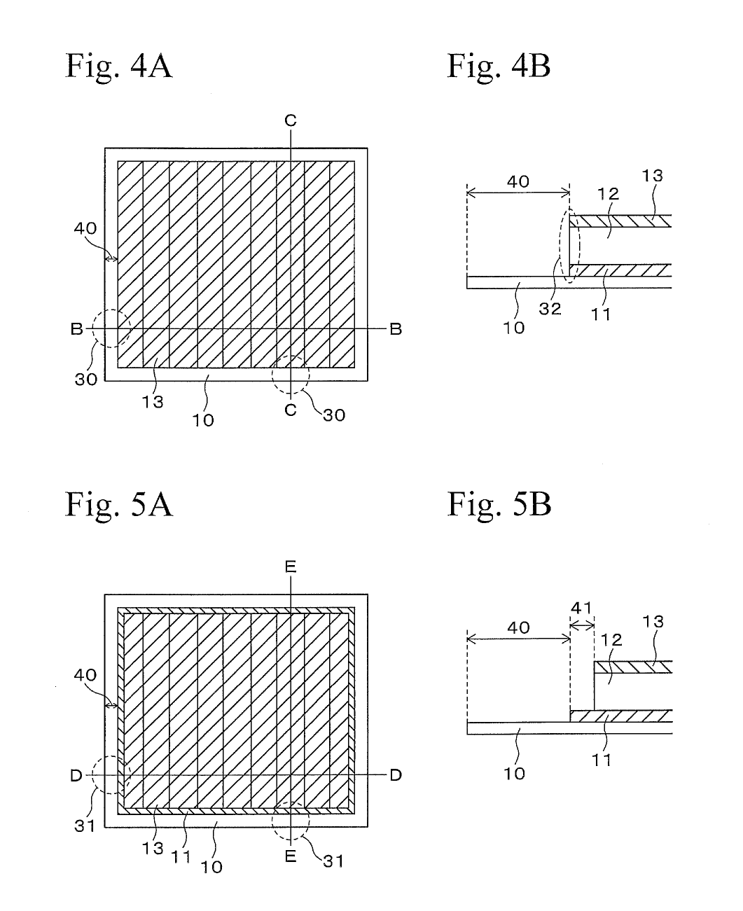

Thin-film solar cell of Comparative Example 1 shown in FIG. 4 was produced in a manner similar to that in the Example, except that the perpendicular groove was not formed.

### Comparative Example 2

Thin-film solar cell of Comparative Example 2 shown in FIG. 5 was produced, by removing an area from the end to a distance the same as the heat relaxation distance of Example 1, 100 μm, by a needle in the thin-film solar cell of Comparative Example 1.

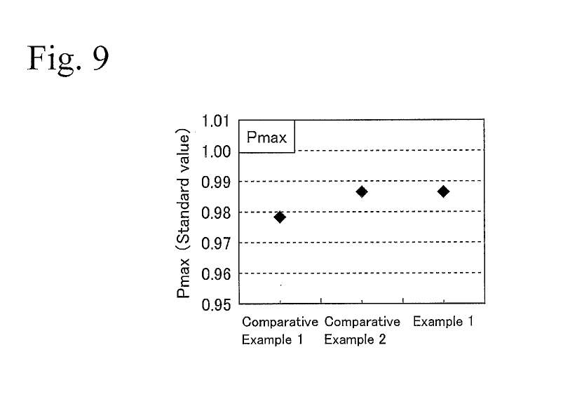

With respect to the thin-film solar cell of Example 1 and Comparative Examples 1 and 2, FF (Fill Factor), shunt resistance Rₛₕ, and maximal output Power Pₘₐₓ were measured. These results are shown in graphs of FIGS. 7 to 9.

It should be noted that the maximal power output Pₘₐₓ is maximal power generating value (W) at predetermined conditions (incident energy, temperature, air mass AM) of the thin-film solar cell. The shunt resistance Rₛₕ is a resistance value (Q) of the solar cell element, and depends on leakage current by modification of the light absorbing layer. FF is a ratio of Pₘₐₓ/P₀ in a case in which ideal maximal power output, which is a product of open voltage V₀ and short circuited current I₀ in a characteristics curve of solar cell, is defined as P₀. It is more desirable as FF becomes larger.

As shown in graphs in FIGS. 7 to 9, compared to Comparative Example 1 in which an end part of the solar cell element is affected by heat of a laser beam, performance is improved in Example 1 in which the heat affected part is separated, and in Comparative example 2 in which the part is removed.

Furthermore, in a comparison between Example 1 and Comparative Example 2, although performances are the same in both, the process for forming the perpendicular groove in Example 1 took less time than the process for removing the end part area in Comparative Example 2. That is, it was confirmed that a thin-film solar cell having similar performance to Comparative Example 2 can be produced more efficiently in the present invention.

The present invention is helpful in producing chalcopyrite-type thin-film solar cells having high power generation efficiency.

### Explanation of Reference Numerals

1: Thin-film solar cell, 10: substrate, 11: back surface electrode layer, 11a to 11d: divided back surface electrode layer, 12: light absorbing layer, 12a to 12d: divided light absorbing layer, 13: transparent electrode layer, 13a to 13d: divided transparent electrode layer, 20: perpendicular groove, 30 to 34: end part, 40 to 42: area to be removed, 43: heat relaxation distance, 44: width of perpendicular groove.

1. A thin-film solar cell comprising:
a substrate, and
a back surface electrode layer, a light-absorbing layer, and a transparent electrode layer, layered on the substrate in this order, the layers divided into multiple unit cells by a scribed groove, and the unit cells serially connected,
wherein at an inside of an end side of the solar cell perpendicular to the scribed groove, a perpendicular groove is formed that is perpendicular to the scribed groove and which is a groove of which above the back surface electrode is removed.

2. The method for producing the thin-film solar cell of claim 1, comprising steps of:
forming a back surface electrode layer on an upper surface of the substrate,
cutting the back surface electrode layer to divide it into multiple back surface electrode layers,
forming a light-absorbing layer and a transparent electrode layer on the multiple back surface electrode layers,
cutting the light-absorbing layer and the transparent layer to form a scribed groove and to divide the solar cell element,
emitting a laser on the solar cell element of an end part of a side perpendicular to the scribed groove so as to form a new end surface by removing the back surface electrode layer, the light-absorbing layer and the transparent electrode layer,
mechanically forming the perpendicular groove, which is formed by removing above the back surface electrode layer perpendicular to the scribed groove, at an inside of the new end surface modified by the laser emission, at a point having a heat relaxation distance from the new end surface, the heat relaxation distance is a distance at which the light absorbing layer is not affected by the modification.

3. The method for producing the thin-film solar cell of claim 1, comprising steps of:
forming a back surface electrode layer on an upper surface of the substrate,
cutting the back surface electrode layer to divide it into multiple back surface electrode layers,
forming a light-absorbing layer and a transparent electrode layer on the multiple back surface electrode layers,
cutting the light-absorbing layer and the transparent layer to form a scribed groove and to divide the solar cell element,
a mechanically forming the perpendicular groove, which is formed by removing above the back surface electrode layer perpendicular to the scribed groove, at the solar cell element of an end part of a side perpendicular to the scribed groove,
emitting a laser beam on a part which is apart at a predetermined distance or more from the perpendicular groove of a remaining solar cell element at an end part of a side perpendicular to the scribed groove, so as to remove the back surface electrode layer, the light-absorbing layer and the transparent electrode layer, in order that the light absorbing layer of inside of the perpendicular groove is not affected by modification of the laser emission.

4. (canceled)
